(19) United States
(12) Patent Application Publication
(10) Pub. No.: US 2014/0290714 A1
(43) Pub. Date: Oct. 2, 2014

(54) GLASS COATED WITH A HIGHLY REFLECTIVE FILM AND PROCESS FOR PREPARING THE SAME

(71) Applicant: Changzhou Almaden Co., Ltd., Changzhou (CN)

(72) Inventors: JINXI LIN, Changzhou (CN); Jinhan Lin, Changzhou (CN); Ling Chen, Changzhou (CN); Guoxiang Wang, Changzhou (CN); Zhilong Ni, Changzhou (CN)

(73) Assignee: Changzhou Almaden Co., Ltd., Changzhou (CN)

(21) Appl. No.: 14/226,420

(22) Filed: Mar. 26, 2014

(30) Foreign Application Priority Data
Mar. 27, 2013 (CN) 201310101101.3

(51) Int. Cl. H01L 31/052; B05D 5/06; G02B 5/08

(52) U.S. Cl. CPC H01L 31/0527; G02B 5/08; B05D 5/063
USPC 136/246; 359/838; 359/350; 427/372.2; 427/600; 427/240; 427/397.7; 427/386; 427/387; 427/389.7

(57) ABSTRACT

The present invention discloses a glass coated with a highly reflective film and the process for preparing the same. The present invention provides a glass coated with a highly reflective film comprising a glass substrate and a highly reflective film formed thereon, wherein the highly reflective film comprises inorganic film-forming materials, adhesives and solvents. The present invention also provides a process for preparing a glass coated with a highly reflective film comprising the following steps: (1) preparing a coating solution; (2) coating the coating solution on a glass; and (3) curing the coated glass. The coated glass is white. Compared with conventional fluorine-containing back sheet materials, the coated glass of the present invention has excellent reflectivity, thermal conductivity, water resistance, mechanical properties and weatherability. Further, the manufacture of the present invention is simple, cost efficient and suitable for large-scale commercialization.

### BACKGROUND OF THE INVENTION

1. Field of the Invention

The present invention is related to a glass coated with a highly reflective film and the process for preparing the same. The coated glass has excellent thermal conductivity, water resistance, improved mechanical properties and weatherability and is useful for photovoltaic cells. Meanwhile, the present invention may be applied to lighting equipment or other products in which reflectivity is needed.

2. Description of the Related Art

Due to global warming and other environmental problems resulting from exploitation of fossil fuels and carbon dioxide emissions, there is urgent need in the industry to find efficient and environmentally friendly alternative energy sources, such as solar energy. Generally, solar cells, also called photovoltaic cells, are devices which convert light energy from the sun into electricity.

The current solar cell assembly generally comprises photovoltaic glass, solar cells, ethylene vinyl acetate (EVA), a back sheet, a junction box and encapsulating materials. The back sheet is placed at the backside of the solar cell assembly to support and protect the solar cells. Since solar cell assemblies are desirably used for outdoor and long-term applications, the back sheets are required to possess excellent weatherability and water-resistance.

Conventional back sheets are generally made from fluorine-containing polymers; however, there is still room for improvement of such fluorine-containing materials in terms of weatherability, UV resistance, water resistance and mechanical strength. Further, fluorine-containing back sheet materials are often expensive. In light of these drawbacks of conventional fluorine-containing back sheet materials, attempts have been made to find an alternative fluorine-containing back sheet material. CN 102301492 A discloses a process to improve the heat resistance and weatherability of back sheets by introducing other resins, adhesives and blocking particles into fluorine-containing materials. However, the anti-aging performance and mechanical strength of such organic materials still fail to meet expectations.

Recently, glasses have been used as an alternative material for back sheets intended for outdoor and long-term applications in light of their outstanding water resistance and weatherability and high mechanical strength. Glasses also have better thermal conductivity than conventional fluorine-containing back sheets. Therefore, the heat produced by the work of a solar cell can be efficiently transferred to the surroundings and overheating of the solar cell may be prevented, along with the consequent lowering of conversion efficiency. However, glasses without any specific treatment transmit light within a wavelength region including visible wavelength and near infrared wavelength by more than 85%. Such high transmission limits the effective utilization of solar light in solar cells. CN 1834701 A discloses a sputtering coating process to coat multiple layered and highly reflective silver and aluminum films on the surface of a glass. However, such structure is complicated and cost-inefficient for solar cell applications.

In light of the foregoing, the present invention provides a coated glass with high reflectivity, high thermal conductivity, excellent water-resistance, improved mechanical properties and weatherability and the process for preparing the same.

### SUMMARY OF THE INVENTION

To address the foregoing technical problems in the prior art, the present invention provides a glass coated with a highly reflective film, characterized in that it comprises a glass substrate and a highly reflective film formed on the glass substrate, wherein the highly reflective film comprises inorganic film-forming materials, adhesives and solvents.

The object of the present invention is to provide a process for preparing a glass coated with a highly reflective film, comprising the following steps: (1) preparing a coating solution; (2) coating the coating solution on a glass; and (3) curing the coated glass.

### BRIEF DESCRIPTION OF THE DRAWING

FIG. 1 shows the reflectivity of the glass coated with a highly reflective film and the fluorine-containing back sheet material.

### DETAILED DESCRIPTION OF THE PRESENT INVENTION

According to one embodiment of the present invention, the process for preparing the glass coated with a highly reflective film comprises: (1) providing a glass substrate; (2) applying a highly reflective film composition comprising inorganic film-forming materials, adhesives and solvents to the surface of the glass substrate; and (3) curing the coated glass.

The steps in the process of the present invention are illustrated below.

(1) preparing a coating solution: mixing inorganic film-forming materials, adhesives, additives and solvents of certain percentages and stirring the mixture at 0° C. to 60° C. for 0.2 to 48 hours; and continuing to stir for 0.2 to 48 hours after the addition of catalysts, wherein the contents of the main components are provided by weight as follows:
inorganic film-forming materials: 3% to 30%;
adhesives: 3% to 30%;
catalysts: 0% to 1%;
additives: 0% to 20%; and
solvents: 20% to 70%.

(2) coating the coating solution on a glass: the coating solution prepared by Step (1) is uniformly applied onto the surface of the glass by roll coating, spray coating, dip coating, slot coating, spin coating, printing, supersonic atomization or combinations thereof.

(3) curing the coated glass: the coated glass is subjected to a curing treatment at a temperature from 0° C. to 800° C. for 30 seconds to 60 hours to provide a glass coated with a highly reflective film.

According to one embodiment of the present invention, the inorganic film-forming material, adhesives and solvents of certain percentages is Step (1) are mixed and stirred at about 0° C. to about 60° C., preferably about 15° C. to about 50° C., more preferably about 25° C. to about 40° C. for about 0.2 to about 48 hours, preferably about 3 to about 20 hours, more preferably about 5 to about 10 hours (depending on the adopted stirring temperatures). The mixture is stirred for about 0.2 to about 48 hours, preferably about 5 to about 25 hours, more preferably about 10 to about 20 hours after the addition of catalysts.

According to one embodiment of the present invention, the highly reflective film is an inorganic ceramic material or an inorganic-organic composite material.

According to one embodiment of the present invention, the coated glass is cured at a temperature from about 0° C. to about 800° C., preferably from about 150° C. to about 500° C., more preferably from about 200° C. to about 450° C. for a curing period from about 30 seconds to about 60 hours, preferably about 2 minutes to about 1 hour, more preferably about 2 minutes to about 0.5 hour (depending on the adopted curing temperature).

According to one embodiment of the present invention, the glass substrate may be any suitable materials known to a person skilled in the art, such as including but not limited to sheet glass or rolled glass.

According to one embodiment of the present invention, the glass substrate may be optionally treated with a tempered treatment, a half tempered treatment, a tempered heat treatment, a half tempered heat treatment, a physical tempered treatment or a physical half tempered treatment or without any aforementioned tempered treatment.

According to one embodiment of the present invention, the glass substrate has a thickness of at least about 0.2 mm.

According to one embodiment of the present invention, the highly reflective film on the coated glass has a thickness from about 0.2 μm to about 200 μm.

According to one embodiment of the present invention, the highly reflective film is white.

The inorganic film-forming material in the aforementioned Step (1) may be SiO₂, ZrO₂, BaSO₄, Al₂O₃, CaCO₃, CaSO₄, ZnO, Pb₃O₄, Sb₂O₃, Fe₂O₃, Fe₃O₄, MgO, MgCO₃, lithopone, mica, ceruse, talc powder or titanium dioxide powder or combinations thereof. The inorganic film-forming materials have a particle size ranging from about 0.001 μm to about 50 μm, preferably from about 0.1 μm to about 5 μm, more preferably from about 0.2 μm to about 3 μm. By the total weight of the film, the content of the inorganic film-forming material is from about 3% to about 30%, preferably from about 4% to about 20%, more preferably from about 10% to about 18%.

The adhesives comprise, but are not limited to, the following materials: colloids made from alcohol salts (such as Ti(OR)₄ or Si(OR)₄), organic salts (such as Pb(CH₃COO)₂), inorganic salts (such as Zn(NO₃)₂ and zirconium oxychloride) and/or metal organic compounds; or organic polymers, for example, novolac resins, urea-formaldehyde resins, expoxy resins, polyvinyl acetate, polyvinyl acetate acetate, acrylate, polystyrenes, alkyd resins, polyurethane, polyisocyanate, diacrylate, silanes, polybenzimidazole, polyimide, butyl rubber and the combination thereof. By the total weight of the coated film, the content of the adhesives is from about 3% to about 30%, preferably from about 4% to about 20%, more preferably from about 10% to about 18%.

Optionally, the highly reflective film may comprise one or more following additives: catalysts or auxiliaries. The auxiliaries may be such as emulsifiers, dispersants, polymerization inhibitors, rheological agents, anti-settling agents, siccatives, anti-skinning agents, anti-shrinking agents, anti-impairment agents, anti-oxidation agents, lubricants, release agents, thermal stabilizers, light stabilizers, anti-electrostatic agents, abrasives, thickening agents or defoamers or the combinations thereof. The catalysts may be inorganic acids, organic acids, bases, acidic salts, basic salts or organic ammonium salts or combinations thereof.

The content of the catalysts, if added, is from about 0.001% to about 1%, preferably from about 0.3% to about 0.8%, more preferably from about 0.4% to about 0.7% by the total weight of the coated film. The content of the auxiliaries, if added, is from about 0.001% to about 20%, preferably from about 1% to about 18%, more preferably from about 5% to about 16% by the total weight of the coated film.

The solvents may be water, petroleum solvents, benzene solvents, terpene solvents, alcohol solvents, ether solvents, ketone solvents, ester solvents, chlorinated hydrocarbon solvents, nitro hydrocarbon solvents or amine solvents or combinations thereof. The content of the solvents is from about 20% to about 70%, preferably from about 25% to about 65%, more preferably from about 35% to about 50% by the total weight of the coated film.

The glass coated with a highly reflective film of the present invention is advantageous over the conventional back sheet not only in terms of material properties such as reflectivity, water resistance, mechanical properties and weatherability but also manufacturing considerations such as simplicity of manufacturing and cost efficiency. The solar cells with the coated glass of the present invention meet the requirements for outdoor and long-term applications.

Moreover, the present invention also provides a solar cell assembly, comprising a front glass substrate, the aforementioned glass coated with a highly reflective film as a back protection material, and photovoltaic cells encapsulated between the front glass substrate and the glass coated with a highly reflective film.

According to one embodiment of the present invention, the solar cell assembly may comprise thermoplastic materials, such as but not limited to ethyl vinyl acetate (EVA), filled between the front glass substrate and photovoltaic cells and between the photovoltaic cells and the glass coated with a highly reflective film at the backside.

Although according to the foregoing description, the solar cell of the present invention has the foregoing structure, it is only for illustration purpose and not intended to the limit the present invention.

Except the glass coated with a highly reflective film of the present invention, the solar cell assembly may be prepared by any conventional methods.

### PREFERRED EMBODIMENTS OF THE PRESENT INVENTION

In this context, unless otherwise limited, a singular term (such as “a”) also includes the plural form thereof. In this context, all embodiments and exemplary terms (for example, “such as”) only aim at making the present invention more substantial, but are not intended to limit the scope of the present invention; terms in this specification should not be construed as implying that any component not claimed may form an essential component for implementing the present invention.

### Embodiment 1

The component percentages of the coating solution are provided by weight as follows:

| inorganic film-forming materials: | |
|---|---|
| SiO₂ (particle size: 0.5-2 μm) | 12% |
| titanium oxide powder (particle size: 1-5 μm) | 8% |
| adhesives: | |
| silane coupling agent KH 560 | 8% |
| acrylate | 7% |
| additives: | |
| anti-oxidation agents | 3% |
| light stabilizers | 2% |
| defoamers | 2% |
| catalysts: | |
| HCl | 0.5% |
| solvents: | |
| water | 20% |
| ethanol | 30% |
| vinyl acetate | 7.5%. |

The inorganic film-forming materials, adhesives, additives and solvents are mixed according to the foregoing percentages and stirred at 40° C. for 3 hours. The mixture is stirred for 16 hours after the catalyst is added.

The surface of the glass is uniformly coated with the coating solution by a spray coating process. The glass is baked at 150° C. for 20 minutes to provide a glass coated with a highly reflective film.

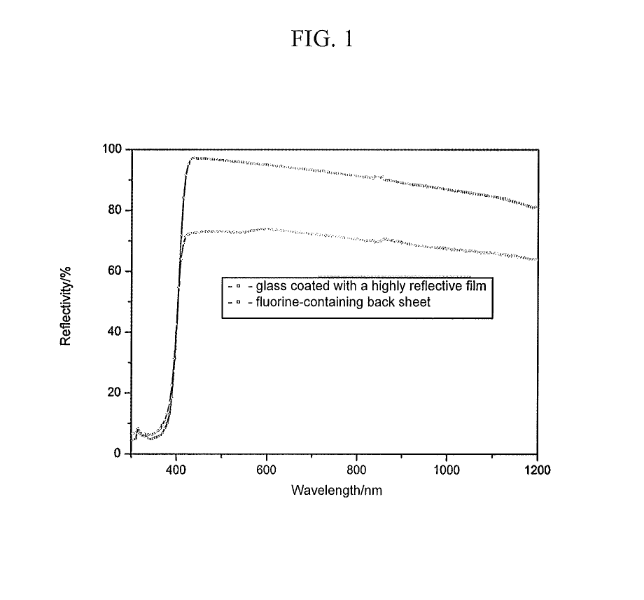

As measured by Lamba 950 and shown in FIG. 1, the glass coated with a highly reflective film has a more than 85% average reflectivity within the visible wavelength region ranging from 380 nm to 780 nm, and a more than 75% average reflectivity within the wavelength region ranging from 300 nm to 1200 nm. Particularly, the glass coated with a highly reflective film of the present invention has an 84.3% average reflectivity within the wavelength region ranging from 300 nm to 1200 nm, and the average reflectivity within the visible wavelength region ranging from 380 nm to 780 nm is 95.65%. Apparently, the coated glass of the present invention is more reflective than the fluorine-containing back sheet material.

### Embodiment 2

The component percentages of the coating solution are provided by weight as follows:

| inorganic film-forming materials: | |
|---|---|
| lithopone (particle size: 1-3 μm) | 10% |
| Al₂O₃ (particle size: 1 μm) | 5% |
| titanium oxide powder (particle size: 1-5 μm) | 3% |
| SiO₂ (particle size: 0.5-2 μm) | 5% |
| adhesives: | |
| tetraethyl orthosilicate | 10% |
| polyurethane | 5% |
| additives: | |
| thickening agents | 4% |
| thermal stabilizers | 5% |
| abrasives | 2% |
| defoamers | 2% |
| catalysts: | |
| oxalic acid | 0.8% |
| solvents: | |
| water | 16% |
| isopropanol | 30% |
| diethylamine | 2.2%. |

The inorganic film-forming materials, adhesives, additives and solvents are mixed according to the foregoing percentages and stirred at 30° C. for 8 hours. The mixture is stirred for 16 hours after the catalyst is added.

The surface of the glass is uniformly coated with the coating solution by a roll coating process. The glass is baked at 200° C. for 25 minutes to provide a glass coated with a highly reflective film.

It should be understood that the foregoing description and the appended drawings are given by way of illustration only without any intention to limit the scope of the present invention. The scope of the invention should only be limited by the appended claims. Various changes and modifications within the spirit and scope of the invention will become apparent to those skilled in the art from this detailed description.

1. A glass coated with a highly reflective film, characterized in that it comprises a glass substrate and a highly reflective film formed on the glass substrate, wherein the highly reflective film comprises inorganic film-forming materials, adhesives and solvents.

2. The glass coated with a highly reflective film according to claim 1, characterized in that the highly reflective film is an inorganic ceramic material or an inorganic-organic composite material.

3. The glass coated with a highly reflective film according to claim 1, characterized in that the average reflectivity within the visible wavelength region ranging from 380 nm to 780 nm is more than 85%, and the average reflectivity within the wavelength region ranging from 300 nm to 1200 nm is more than 75%.

4. The glass coated with a highly reflective film according to claim 1, characterized in that the highly reflective film has a thickness from 0.2 μm to 200 μm.

5. The glass coated with a highly reflective film according to claim 1, characterized in that the highly reflective film is white.

6. The glass coated with a highly reflective film according to claim 1, characterized in that the glass is sheet glass or rolled glass.

7. The glass coated with a highly reflective film according to claim 1, characterized in that the glass may be treated with a tempered heat treatment or a half tempered heat treatment.

8. The glass coated with a highly reflective film according to claim 6, characterized in that the sheet glass or rolled glass has a thickness of at least 0.2 mm.

9. The glass coated with a highly reflective film according to claim 1, characterized in that the glass coated with a highly reflective film has improved mechanical properties, thermal conductivity, water resistance and weatherability.

10. A process for preparing the glass coated with a highly reflective film according to claim 1, characterized in that the process comprises the following steps: (1) preparing a coating solution; (2) coating the coating solution on a glass; and (3) curing the coated glass.

11. The process according to claim 10, wherein the contents by weight of the main components of the coating solution are as follows:
inorganic film-forming materials: 3% to 30%;
adhesives: 3% to 30%;
catalysts: 0% to 1%;
additives: 0% to 20%; and
solvents: 20% to 70%.

12. The process according to claim 10, wherein the coating step may be roll coating, spray coating, dip coating, slot coating, spin coating, printing, supersonic atomization or combinations thereof.

13. The process according to claim 11, wherein the inorganic film-forming materials may be SiO₂, ZrO₂, BaSO₄, Al₂O₃, CaCO₃, CaSO₄, ZnO, Pb₃O₄, Sb₂O₃, Fe₂O₃, Fe₃O₄, MgO, MgCO₃, lithopone, mica, ceruse, talc powder or titanium dioxide powder or combinations thereof.

14. The process according to claim 13, wherein the inorganic film-forming materials have a particle size ranging from 0.001 μm to 50 μm.

15. The process according to claim 11, wherein the adhesives comprise:
(1) colloids made from alcohol salts (such as Ti(OR)₄ or Si(OR)₄), organic salts (such as Pb(CH₃COO)₂), inorganic salts (such as Zn(NO₃)₂ and zirconium oxychloride) and/or metal organic compounds;
(2) organic polymers, for example, novolac resins, urea-formaldehyde resins, expoxy resins, polyvinyl acetate, polyvinyl acetate acetate, acrylate, polystyrene, alkyd resins, polyurethane, polyisocyanate, diacrylate, silanes, polybenzimidazole, polyimide and butyl rubber.

16. The process according to claim 11, wherein the catalysts may be inorganic acids, organic acids, bases, acidic salts, basic salts or organic ammonium salts or combinations thereof.

17. The process according to claim 11, wherein the additives may be emulsifiers, dispersants, polymerization inhibitors, rheological agents, anti-settling agents, siccatives, anti-skinning agents, anti-shrinking agents, anti-impairment agents, anti-oxidation agents, lubricants, release agents, thermal stabilizers, light stabilizers, anti-electrostatic agents, abrasives, thickening agents or defoamers or combinations thereof.

18. The process according to claim 11, wherein the solvent may be water, petroleum solvents, benzene solvents, terpene solvents, alcohol solvents, ether solvents, ketone solvents, ester solvents, chlorinated hydrocarbon solvents, nitro hydrocarbon solvents or amine solvents or combinations thereof.

19. The process according to claim 10, wherein the curing step is carried out at a temperature from 0° C. to 800° C. for a curing period from 30 seconds to 60 hours.

20. A solar cell assembly, comprising:
a front glass substrate;
a glass coated with a highly reflective film according to claim 1; and
photovoltaic cells encapsulated between the front glass substrate and the glass coated with a highly reflective film.
